(19) United States
(12) Patent Application Publication
(10) Pub. No.: US 2025/0220872 A1
(43) Pub. Date: Jul. 3, 2025

(54) SEMICONDUCTOR DEVICE

(71) Applicant: Samsung Electronics Co., Ltd., Suwon-si (KR)

(72) Inventors: Jee Woong KIM, Suwon-si (KR); Kyo-Wook LEE, Suwon-si (KR); Seung Hun LEE, Suwon-si (KR); Keun Hwi CHO, Suwon-si (KR)

(73) Assignee: Samsung Electronics Co., Ltd., Suwon-si (KR)

(21) Appl. No.: 18/776,734

(22) Filed: Jul. 18, 2024

(30) Foreign Application Priority Data
Jan. 2, 2024 (KR) 10-2024-0000305

(51) Int. Cl. H10B 10/00

(52) U.S. Cl. CPC H10B 10/125

(57) ABSTRACT

A semiconductor device may include a pass transistor on a first surface of the substrate, a pulldown transistor sharing an active region with the pass transistor, a pullup transistor sharing a gate with the pulldown transistor, a wordline connected to a gate of the pass transistor, a bitline connected to a drain of the pass transistor, a first power wiring on a second surface of the substrate and connected to a source of the pulldown transistor, and a second power wiring connected to a source of the pullup transistor. A source of the pass transistor and drains of the pulldown and pullup transistors may be connected through one node. The wordline, the bitline, and the second power wiring may be on the first surface of the substrate. A first portion the first power wiring may extend in a direction parallel to a gate of the pass transistor.

### CROSS-REFERENCE TO RELATED APPLICATION

This application claims priority from Korean Patent Application No. 10-2024-0000305 filed on Jan. 2, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a semiconductor device.

### Description of the Related Art

A SRAM (Static Random Access Memory) is a memory device that has a generally high operating speed and requires low operating power, because there is no need to refresh data. A typical application of the SRAM is as a memory element of a mobile device such as a mobile phone. In general, an SRAM memory cell includes two pass transistors and two inverters that form a flip-flop circuit.

When forming an SRAM cell using a CMOS process, it may be difficult to reduce the size of the SRAM cell because six transistors are disposed in a single SRAM cell. In particular, as the process is miniaturized, a margin between the contacts and metal wirings for connecting a large number of transistors and applying signals is decreasing, and this becomes an obstacle to miniaturization of the SRAM cells.

### SUMMARY

Aspects of the present disclosure provide a semiconductor device having improved reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an example embodiment of the present disclosure, a semiconductor device may include a substrate including a first surface and a second surface opposing each other in a first direction; a first active pattern on the first surface and extending in a second direction, the second direction intersecting the first direction; a second active pattern on the first surface and spaced apart from the first active pattern in a third direction, the third direction intersecting the first direction and the second direction, and the second active pattern extending in the second direction; a first gate electrode intersecting the first active pattern and extending in the third direction; a second gate electrode spaced apart from the first gate electrode in the second direction, the second gate electrode intersecting the first active pattern and the second active pattern; a first source/drain pattern on the first active pattern, the first source/drain pattern disposed between the first gate electrode and the second gate electrode; a second source/drain pattern on the first active pattern, the second gate electrode being between the first source/drain pattern and the second source/drain; a third source/drain pattern on the second active pattern and spaced apart from the first source/drain pattern in the third direction; and a first power supply wiring on the second surface and electrically connected to the second source/drain pattern. The first source/drain pattern and the third source/drain may be are electrically shared through a same node. A first portion of the first power supply wiring may extend in the third direction from below the second source/drain pattern.

According to an example embodiment of the present disclosure, a semiconductor device may include a substrate including a first surface and a second surface opposite to each other in a first direction; a pass transistor on the first surface of the substrate; a pull-down transistor sharing an active region with the pass transistor; a pull-up transistor sharing a gate electrode with the pull-down transistor; a word line electrically connected to a gate electrode of the pass transistor; a bit line electrically connected to a drain pattern of the pass transistor; a first power supply wiring electrically connected to a source pattern of the pull-down transistor; and a second power supply wiring electrically connected to a source pattern of the pull-up transistor. A source pattern of the pass transistor, a drain pattern of the pull-down transistor, and a drain pattern of the pull-up transistor may be electrically connected through one node. The first power supply wiring may be on the second surface. The word line, the bit line, and the second power supply wiring may be on the first surface. A first portion of the first power supply wiring may extend in a direction parallel to an extension direction of a gate electrode of the pass transistor.

According to an example embodiment of the present disclosure, a semiconductor device may include a substrate including a first NMOS region, a second NMOS region, a PMOS region between the first NMOS region and the second NMOS region, the substrate including a first surface and a second surface opposite to each other in a first direction; a first pass transistor and a first pull-down transistor on the first surface of the substrate of the first NMOS region; a second pass transistor and a second pull-down transistor on the first surface of the substrate of the second NMOS region; a first pull-up transistor on the first surface of the substrate of the PMOS region, the first pull-up transistor sharing a gate electrode with the first pull-down transistor; a second pull-up transistor on the first surface of the substrate of the PMOS region and sharing a gate electrode with the second pull-down transistor; a first power supply wiring configured to apply a negative voltage to each of a source pattern of the first pull-down transistor and a source pattern of the second pull-down transistor; and a second power supply wiring configured to apply a positive voltage to each of a source pattern of the first pull-up transistor and a source pattern of the second pull-up transistors. The first pass transistor and the first pull-down transistor may share an active region. The second pass transistor and the second pull-down transistor may share a same active region. A source pattern of the first pass transistor, a drain pattern of the first pull-down transistor, and a drain pattern of the first pull-up transistor may be electrically connected through one first node. A source pattern of the second pass transistor, a drain pattern of the second pull-down transistor, and a drain pattern of the second pull-up transistor may be electrically connected through one second node. The first power supply wiring may be on the second surface of the substrate. The second power supply wiring may be on the first surface of the substrate. The first power supply wiring may extend in a direction parallel to an extension direction of the gate electrode of the first pass transistor and an extension direction of the gate electrode of the second pass transistor. The second power supply wiring may extend in a direction parallel to an extension direction of an active pattern of the first pass transistor and an extension direction of an active pattern of the second pass transistor.

### BRIEF DESCRIPTION OF THE DRAWINGS

The above and other aspects and features of the present disclosure will become more apparent by describing in detail example embodiments thereof with reference to the attached drawings, in which:

FIG. 1 is an example circuit diagram for explaining the semiconductor device according to some embodiments.

FIG. 2 is an example layout diagram for explaining a semiconductor device according to some embodiments of the present disclosure.

FIG. 3 is an enlarged view of a region C1 of FIG. 2.

FIG. 4 is an example cross-sectional view taken along a line A1-A1 of FIG. 3.

FIG. 5 is an example cross-sectional view taken along a line A2-A2 of FIG. 3.

FIG. 6 is an example cross-sectional view taken along a line A3-A3 of FIG. 3.

FIG. 7 is an example cross-sectional view taken along a line A4-A4 of FIG. 3.

FIG. 8 is an example layout diagram for explaining a semiconductor device according to some other embodiments of the present disclosure.

FIG. 9 is an example cross-sectional view taken along a line B1-B1 of FIG. 8.

FIGS. 10 and 11 are example cross-sectional views taken along a line B2-B2 of FIG. 8.

FIGS. 12 to 16 are example diagrams for explaining a semiconductor device according to some other embodiments of the present disclosure.

### DETAILED DESCRIPTION OF THE EMBODIMENTS

Although drawings of the semiconductor device according to some embodiments show a transistor including a nanowire or a nanosheet, and a MBCFET™ (Multi-Bridge Channel Field Effect Transistor) as an example, example embodiments are not limited thereto. Semiconductor devices according to some embodiments may, of course, include a tunneling transistor (tunneling FET) or a three-dimensional (3D) transistor. The semiconductor device according to some embodiments may, of course, include a planar transistor. In addition, the technical idea of the present disclosure may be applied to a transistor based on two-dimensional material (2D material based FETs) and a heterostructure thereof.

Further, semiconductor devices according to some embodiments may also include a bipolar junction transistor, a laterally diffused metal oxide semiconductor (LDMOS), or the like.

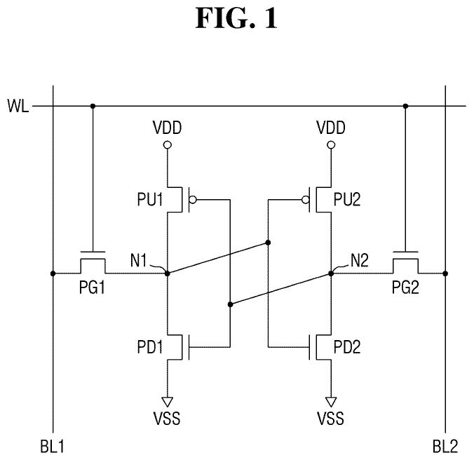

Embodiments according of technical ideas of the present disclosure will be described below with reference to the accompanying drawings. First, the semiconductor device according to some embodiments of the present disclosure will be described with reference to FIGS. 1 to 3.

FIG. 1 is an example circuit diagram for explaining the semiconductor device according to some embodiments.

Referring to FIG. 1, the semiconductor device according to some embodiments may include at least one or more cells. Each cell may include first and second bit lines BL1 and BL2, a word line WL, and a plurality of transistors. That is, FIG. 1 may be a circuit diagram showing one of a plurality of cells of the semiconductor device.

Specifically, the semiconductor device includes may include a first pass transistor PG1, a second pass transistor PG2, a first pull-up transistor PU1, a second pull-up transistor PU2, a first pull-down transistor PD1, and a second pull-down transistor PD2.

The first pull-up transistor PU1 and the second pull-up transistor PU2 may be a P-type MOSFET (metal-oxide-semiconductor field effect transistor). The first pass transistor PG1, the second pass transistor PG2, the first pull-down transistor PD1, and the second pull-down transistor PD2 may be N-type MOSFETs. That is, the semiconductor device may include six transistors including four NMOS transistors and two PMOS transistors.

Switching electrodes (e.g., gate electrodes) of the first and second pass transistors PG1 and PG2 may be connected to the word line WL. A drain pattern of the first pass transistor PG1 may be connected to a first bit line BL1. A drain pattern of the second pass transistor PG2 may be connected to the second bit line BL2. A positive voltage VDD may be applied to a source pattern of the first pull-up transistor PU1. The positive voltage VDD may be applied to a source pattern of the second pull-up transistor PU2. A negative voltage VSS may be applied to a source pattern of the first pull-down transistor PD1. The negative voltage VSS may be applied to a source pattern of the second pull-down transistor PD2.

The source pattern of the first pass transistor PG1, the drain pattern of the first pull-up transistor PU1, and the drain pattern of the first pull-down transistor PD1 may be commonly connected to the first node N1.

The source pattern of the second pass transistor PG2, the drain pattern of the second pull-up transistor PU2, and the drain pattern of the second pull-down transistor PD2 may be commonly connected to the second node N2.

A switching electrode (e.g., gate electrode) of the first pull-up transistor PU1 and a switching electrode (e.g., gate electrode) of the first pull-down transistor PD1 may be commonly connected to the second node N2. A switching electrode (e.g., gate electrode) of the second pull-up transistor PU2 and a switching electrode (e.g., gate electrode) of the second pull-down transistor PD2 may be commonly connected to the first node N1. Accordingly, the first and second pull-up transistors PU1 and PU2 and the first and second pull-down transistors PD1 and PD2 may constitute a latch circuit including a pair of CMOS inverters.

When a high signal is applied to the first node N1, the second pull-up transistor PU2 is turned off, the second pull-down transistor PD2 is turned on, and a low signal is applied to the second node N2. As the low signal is applied to the second node N2, the first pull-up transistor PU1 is turned on, the second pull-down transistor PD2 is turned off, and the first node N1 maintains a high signal.

When the high signal is applied to the second node N2, the first pull-up transistor PU1 is turned off, the first pull-down transistor PD1 is turned on, and the low signal is applied to the first node N1. As the low signal is applied to the first node N1, the second pull-up transistor PU2 is turned on, the second pull-down transistor PD2 is turned off, and the second node N2 maintains the high signal.

Therefore, the first and second pass transistors PG1 and PG2 are turned on in response to the switching signal applied to the word line WL. At this time, the data signals supplied to the first and second bit lines BL1 and BL2 may be latched to the first and second nodes N1 and N2 through the first and second pass transistors PG1 and PG2. When the first and second pass transistors PG1 and PG2 are turned on, the data latched to the first and second nodes N1 and N2 may be provided to the first and second bit lines BL1 and BL2 through the first and second pass transistors PG1 and PG2. The data latched to the first and second nodes N1 and N2 may be read by sensing the signals provided to the first and second bit lines BL1 and BL2 through the sense amplifier.

The first pass transistor PG1 may share the active region with the first pull-down transistor PD1. The second pass transistor PG2 may share the active region with the second pull-down transistor PD2. The first pull-down transistor PD1 may share the gate electrode with the first pull-up transistor PU1. The second pull-down transistor PD2 may share the gate electrode with the second pull-up transistor PU2. The gate electrodes of each of the first pass transistor PG1 and the second pass transistor PG2 are not shared with the gate electrodes of other transistors.

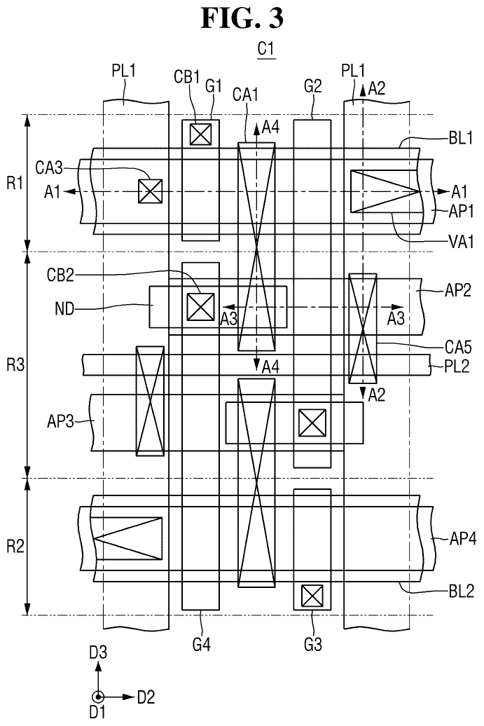

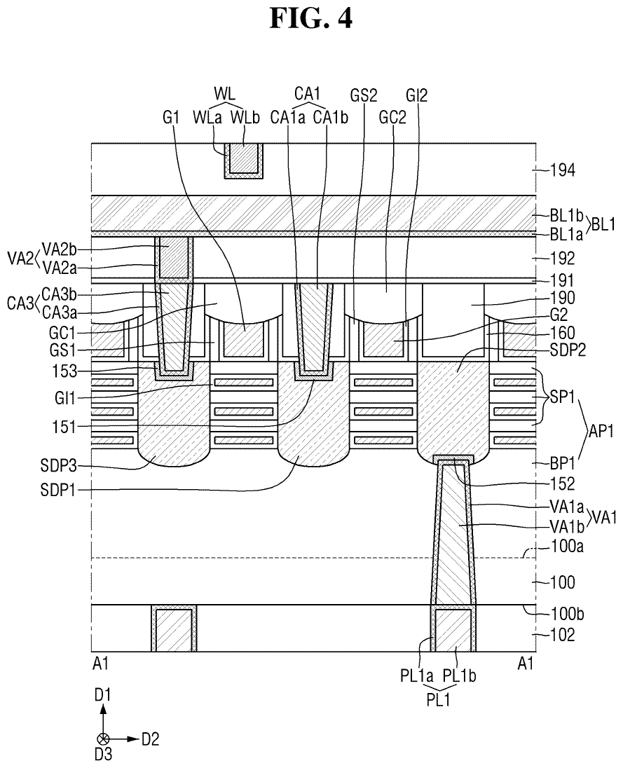

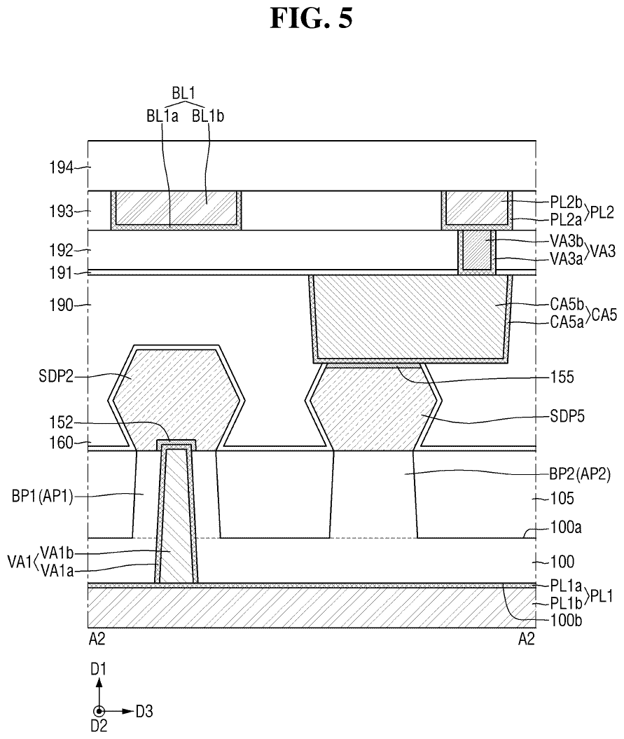

In some embodiments, a first power supply wiring (e.g., PL1 of FIG. 4) for applying the negative voltage to the source patterns of the first pull-down transistor PD1 and the second pull-down transistor PD2 may be disposed below the substrate. A second power supply wiring (for example, PL2 of FIG. 5) for applying the positive voltage to the source patterns of the first pull-up transistor PU1 and the second pull-up transistor PU2 may be disposed above the substrate. Further, the word line WL and the first and second bit lines BL1 and BL2 may be disposed above the substrate. This will be explained in detail using FIGS. 3 to 7.

In some embodiments, the first pull-down transistor PD1 and the second pull-down transistor PD2 may be a N-type MOSFET (metal-oxide-semiconductor field effect transistors). The first pass transistor PG1, the second pass transistor PG2, the first pull-up transistor PU1, and the second pull-up transistor PU2 may be a P-type MOSFET. That is, the semiconductor device may include six transistors made up of four PMOS transistors and two NMOS transistors.

The first pass transistor PG1 may share the active region with the first pull-up transistor PU1. The second pass transistor PG2 may share the active region with the second pull-up transistor PU2. The first pull-down transistor PD1 may share the gate electrode with the first pull-up transistor PU1. The second pull-down transistor PD2 may share the gate electrode with the second pull-up transistor PU2. The gate electrodes of each of the first pass transistor PG1 and the second pass transistor PG2 are not shared with the gate electrodes of other transistors.

In some embodiments, a power supply wiring for applying the positive voltage to the source patterns of the first pull-up transistor PU1 and the second pull-up transistor PU2 may be disposed below the substrate. A power supply wiring for applying the negative voltage to the source patterns of the first pull-down transistor PD1 and the second pull-down transistor PD2 may be disposed above the substrate. Further, the word line WL and the first and second bit lines BL1 and BL2 may be disposed above the substrate.

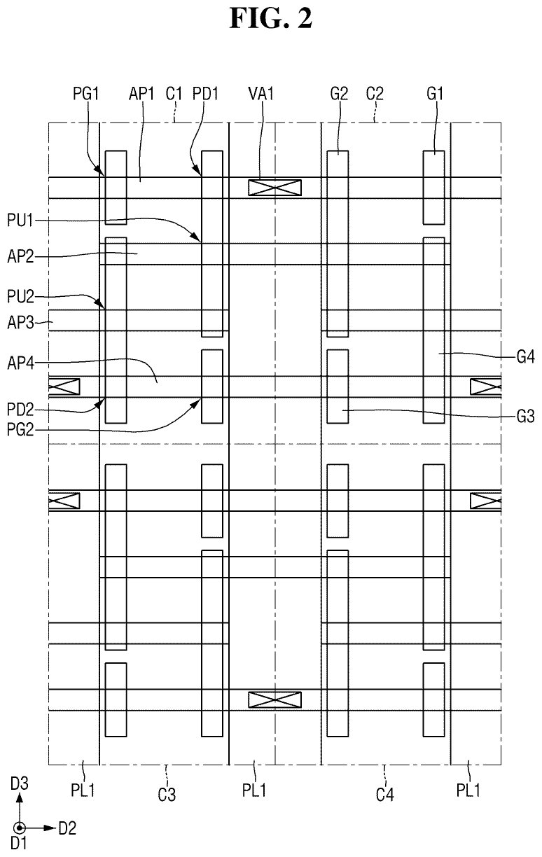

FIG. 2 is an example layout diagram for explaining a semiconductor device according to some embodiments of the present disclosure.

Referring to FIG. 2, the semiconductor device according to some embodiments may include a first cell region C1, a second cell region C2, a third cell region C3, and a fourth cell region C4.

In FIG. 2, although the semiconductor device is shown to include four cell regions C1, C2, C3, and C4, technical ideas of the present disclosure are not limited thereto. It goes without saying that the semiconductor device of the present disclosure may include five or more cell regions.

The first cell region C1 may be adjacent to the second cell region C2 and the third cell region C3. The first cell region C1 and the second cell region C2 may be adjacent to each other in the second direction D2. The first cell region C1 and the third cell region C3 may be adjacent to each other in the third direction D3. In this specification, the first direction D1, the second direction D2, and the third direction D3 may intersect each other. The first direction D1 may be a direction that is substantially perpendicular to an upper surface of the substrate, and each of the second direction D2 and the third direction D3 may be substantially parallel to the upper surface of the substrate.

A layout structure of the first cell region C1 may be symmetrical to a layout structure of the second cell region C2 on the basis of the third direction D3. The layout structure of the first cell region C1 may be symmetrical with a layout structure of the third cell region C3 on the basis of the second direction D2.

Similarly, the fourth cell region C4 may be adjacent to the second cell region C2 and the third cell region C3. The fourth cell region C4 and the second cell region C2 may be adjacent to each other in the third direction D3. The fourth cell region C4 and the third cell region C3 may be adjacent to each other in the second direction D2. A layout structure of the fourth cell region C4 may be symmetrical to the layout structure of the second cell region C2 on the basis of the second direction D3. The layout structure of the fourth cell region C4 may be symmetrical with the layout structure of the third cell region C3 on the basis of the third direction D3.

Since the first cell region C1, the second cell region C2, the third cell region C3, and the fourth cell region C4 may be substantially the same, only the first cell region C1 will be described below.

For example, the first cell region C1 may include first and second pass transistors PG1 and PG2, first and second pull-down transistors PD1 and PD2, and first and second pull-up transistors PU1 and PU2.

Further, the first cell region C1 may include a first gate electrode G1, a second gate electrode G2, a third gate electrode G3, and a fourth gate electrode G4. The first cell region C1 may include a first active pattern AP1, a second active pattern AP2, a third active pattern AP3, and a fourth active pattern AP4.

The first pass transistor PG1 and the first pull-down transistor PD1 may share the first active pattern AP1. The gate electrode of the first pass transistor PG1 may be the first gate electrode G1. The first pull-down transistor PD1 and the first pull-up transistor PU1 may share the second gate electrode G2. The active pattern of the first pull-up transistor PU1 may be the second active pattern AP2.

The second pass transistor PG2 and the second pull-down transistor PD2 may share the fourth active pattern AP4. The gate electrode of the second pass transistor PG2 may be the third gate electrode G3. The second pull-down transistor PD2 and the second pull-up transistor PU2 may share the fourth gate electrode G4. The active pattern of the second pull-up transistor PU2 may be the third active pattern AP3.

The semiconductor device according to some embodiments may include first power supply wirings PL1. The first power supply wirings PL1 may be electrically connected to the source pattern of the first pull-down transistor PD1 and the source pattern of the second pull-down transistor PD2. The source pattern of the first pull-down transistor PD1 and the source pattern of the second pull-down transistor PD2 may each be electrically connected to the first power supply wiring PL1 through the first via VA1. The first power supply wiring PL1 may apply the negative voltage VSS to the source pattern of the first pull-down transistor PD1 and the source pattern of the second pull-down transistor PD2.

The first power supply wiring PL1 may extend in the third direction D3. The first power supply wiring PL1 may extend in the same direction as an extension direction of the gate electrodes G1, G2, G3, and G4. Further, the first power supply wiring PL1 may be disposed below the transistor. That is, the first power supply wiring PL1 may be disposed below the substrate. Further, the first power supply wiring PL1 may be disposed to overlap in the first direction D1 with each of two cells adjacent in the second direction D2. This will be explained in more detail using FIGS. 3 to 7.

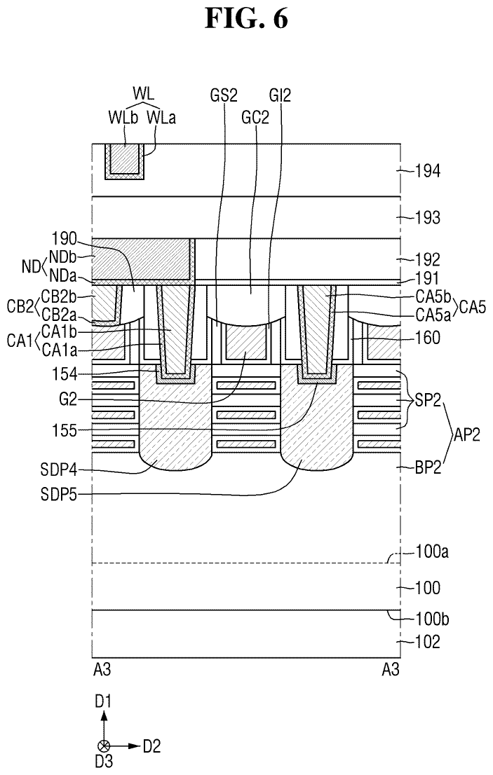

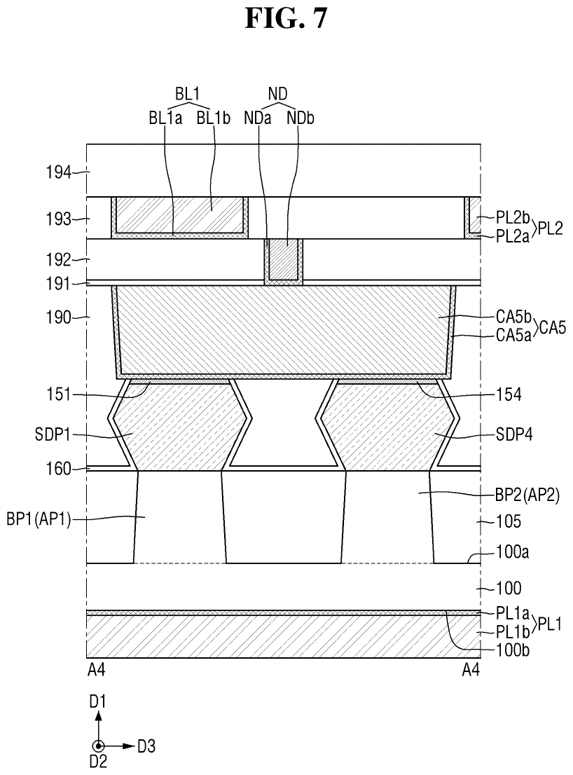

FIG. 3 is an enlarged view of a region C1 of FIG. 2. FIG. 4 is an example cross-sectional view taken along a line A1-A1 of FIG. 3. FIG. 5 is an example cross-sectional view taken along a line A2-A2 of FIG. 3. FIG. 6 is an example cross-sectional view taken along a line A3-A3 of FIG. 3. FIG. 7 is an example cross-sectional view taken along a line A4-A4 of FIG. 3.

Referring to FIGS. 3 to 7, the semiconductor device according to some embodiments may include the first active pattern AP1, the second active pattern AP2, the third active pattern AP3, the fourth active pattern AP4, the first gate electrode G1, the second gate electrode G2, the third gate electrode G3, and the fourth gate electrode G4.

First, a substrate 100 may be provided. The substrate 100 may include a plurality of active regions and field regions. Each of the plurality of active regions may be regions in which the first active pattern AP1, the second active pattern AP2, the third active pattern AP3 or the fourth active pattern AP4 is disposed. The field region may be formed directly adjacent to the plurality of active regions. The field region may form a boundary with the plurality of active regions.

The plurality of active regions are spaced apart from each other. The plurality of active regions may be separated by the field region. In other words, an element isolation film may be disposed around the plurality of active regions that are spaced apart from each other. At this time, a portion of the element isolation film between the plurality of active regions may be the field region. For example, a portion in which a channel region of a transistor, which may be an example of a semiconductor device, is formed may be the active region, and a portion that divides the channel region of the transistor formed in the active region may be the field region. Alternatively, the active region may be a portion in which a fin-shaped pattern or nanosheet used as the channel region of the transistor is formed, and the field region may be a region in which the fin-shaped pattern or nanosheet used as the channel region is not formed.

The substrate 100 may include a first surface 100a and a second surface 100b that are opposite to each other in a first direction D1. The substrate 100 may be a silicon substrate or silicon-on-insulator (SOI). In contrast, the substrate 100 may include, but not limited to, silicon-germanium, silicon germanium on insulator (SGOI), indium antimonide, lead telluride, indium arsenide, indium phosphide, gallium arsenide or gallium antimonide.

The substrate 100 may include a first region R1, a second region R2, and a third region R3. The third region R3 may be interposed between the first region R1 and the second region R2. The first active pattern AP1 is disposed on the substrate 100 of the first region R1. Two transistors may be disposed on the substrate 100 of the first region R1. The fourth active pattern AP4 is disposed on the substrate 100 of the second region R2. Two transistors may be disposed on the substrate 100 of the second region R2. The second active pattern AP2 and the third active pattern AP3 are disposed on the substrate 100 of the third region R3. Two transistors may be disposed on the substrate 100 of the third region R3.

In some embodiments, the first region R1 and the second region R2 may be a first NMOS region and a second NMOS region, respectively. At this time, the third region R3 may be a PMOS region. The first pass transistor and the first pull-down transistor are disposed on the substrate 100 of the first NMOS region. A second pass transistor and a second pull-down transistor are disposed on the substrate 100 of the second NMOS region. A first pull-up transistor and a second pull-up transistor are disposed on the substrate 100 of the PMOS region.

In another embodiment, the first region R1 and the second region R2 may be a first PMOS region and a second PMOS region, respectively. At this time, the third region R3 may be an NMOS region. The first pass transistor and the first pull-up transistor are disposed on the substrate 100 of the first PMOS region. The second pass transistor and the second pull-up transistor are disposed on the substrate 100 of the second PMOS region. The first pull-down transistor and the second pull-down transistor are disposed on the substrate 100 of the NMOS region.

Hereinafter, the description will be provided on the assumption that the first region R1 and the second region R2 are each of the first and second NMOS regions, and the third region R3 is the PMOS region.

The first active pattern AP1, the second active pattern AP2, the third active pattern AP3, and the fourth active pattern AP4 may each be disposed on the first surface 100a of the substrate 100. The first active pattern AP1, the second active pattern AP2, the third active pattern AP3, and the fourth active pattern AP4 may extend long on the substrate 100 along the second direction D2. The first active pattern AP1, the second active pattern AP2, the third active pattern AP3, and the fourth active pattern AP4 may be spaced apart from each other in the third direction D3.

From viewpoint of a plan view, the first active pattern AP1, the second active pattern AP2, the third active pattern AP3, and the fourth active pattern AP4 may each include a long surface extending in the second direction D2, and a short surface extending in the third direction D3. Here, the second direction D2 may intersect the third direction D3 and the first direction D1. Further, the third direction D3 may intersect the first direction D1. The first direction D1 may be a thickness direction of the substrate 100.

Each of the first active pattern AP1, the second active pattern AP2, the third active pattern AP3, and the fourth active pattern AP4 may be a multi-channel active pattern. The first active pattern AP1 may include a first lower pattern BP1 and a plurality of first sheet patterns SP1. The second active pattern AP2 may include a second lower pattern BP2 and a plurality of second sheet patterns SP2. Although not shown, the third active pattern AP3 may include a third lower pattern and a plurality of third sheet patterns. The fourth active pattern AP4 may include a fourth lower pattern and a plurality of fourth sheet patterns. For convenience of explanation, description of the third active pattern AP3 and the fourth active pattern AP4 will be omitted.

The first lower pattern BP1 may protrude from the substrate 100 in the first direction D1. The first lower pattern BP1 may extend long in the second direction D2. The first lower pattern BP1 may be a fin-shaped pattern. A plurality of first sheet patterns SP1 may be disposed on the first lower pattern BP1. The plurality of first sheet patterns SP1 may be spaced apart from the first lower pattern BP1 in the first direction D1. Furthermore, the plurality of first sheet patterns SP1 may be spaced apart from each other in the first direction D1. Although three first sheet patterns SP1 are shown as being disposed in the first direction D1, this is only for convenience of explanation, and the embodiment is not limited thereto.

The second lower pattern BP2 may protrude from the substrate 100 in the first direction D1. The second lower pattern BP2 may extend long in the second direction D2. The second lower pattern BP2 may be a fin-shaped pattern. Although not shown, a plurality of second sheet patterns SP2 may be disposed on the second lower pattern BP2. The plurality of second sheet patterns SP2 may be spaced apart from the second lower pattern BP2 in the first direction D1. Furthermore, the plurality of second sheet patterns SP2 may be spaced apart from each other in the first direction D1.

The first lower pattern BP1 and the second lower pattern BP2 may each be formed by etching a part of the substrate 100, or may include an epitaxial layer grown from the substrate 100. The first lower pattern BP1 and the second lower pattern BP2 may each include silicon or germanium, which is an elemental semiconductor material. Further, the first lower pattern BP1 and the second lower pattern BP2 may each include a compound semiconductor, and may include a group IV-IV compound semiconductor or a group III-V compound semiconductor.

The group IV-IV compound semiconductor may be, for example, a binary compound or a ternary compound including at least two or more of carbon (C), silicon (Si), germanium (Ge), and tin (Sn), or a compound obtained by doping these elements with a group IV element.

The group III-V compound semiconductor may be, for example, one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

The first sheet patterns SP1 and the second sheet patterns SP2 may each include one of silicon or germanium which are elemental semiconductor materials, a group IV-IV compound semiconductor or a group III-V compound semiconductor. Each first sheet pattern SP1 may include the same material as the first lower pattern BP1, or may include a different material from the first lower pattern BP1. Each second sheet pattern SP2 may include the same material as the second lower pattern BP2, and may include a different material from the second lower pattern BP2.

In the semiconductor device according to some embodiments, the first lower pattern BP1 and the second lower pattern BP2 may be a silicon lower pattern including silicon, and the first sheet pattern SP1 and the second sheet pattern may be a silicon sheet pattern including silicon.

A field insulating film 105 may be formed on the first substrate 100. The field insulating film 105 may be formed on the first surface 100a of the first substrate 100.

The field insulating film 105 may cover the side walls of the first lower pattern BP1 and the side walls of the second lower pattern BP2. Each first sheet pattern SP1 and each second sheet pattern are disposed to be higher than the upper surface of the field insulating film 105. The field insulating film 105 may include, for example, an oxide film, a nitride film, an oxynitride film or a combination thereof. Although the field insulating film 105 is shown as being a single film, the embodiment is not limited thereto. Unlike the shown example, the field insulating film 105 may include a field liner which extends along the side walls and a bottom surface of a fin trench that defines the first and second lower patterns BP1 and BP2, and a field filling film on the field liner.

The first to fourth gate electrodes G1, G2, G3, and G4 may be disposed on the first surface 100a of the substrate 100. The first to fourth gate electrodes G1, G2, G3, and G4 may be disposed on the field insulating film 105. The first to fourth gate electrodes G1, G2, G3, and G4 may each extend in the third direction D3.

The first gate electrode G1 may be disposed on the first active pattern AP1. The first gate electrode G1 may intersect the first active pattern AP1. The first gate electrode G1 may surround the first sheet pattern SP1. The second gate electrode G2 may be disposed on the first active pattern AP1, the second active pattern AP2, and the third active pattern AP3. The second gate electrode G2 may intersect each of the first active pattern AP1, the second active pattern AP2, and the third active pattern AP3. The second gate electrode G2 may surround the first sheet pattern SP1, the second sheet pattern SP2, and the third sheet pattern. The third gate electrode G3 may be disposed on the fourth active pattern AP4. The fourth gate electrode G4 may be disposed on the second active pattern AP2, the third active pattern AP3, and the fourth active pattern AP4.

In FIG. 4, although the upper surface of the first gate electrode G1 and the upper surface of the second gate electrode G2 may each be a convex curved surface that is recessed toward the upper surface of the first lower pattern BP1, the embodiment is not limited thereto. That is, unlike the shown example, the upper surface of the first gate electrode G1 and the upper surface of the second gate electrode G2 may be flat planes.

The first to fourth gate electrodes G1, G2, G3, and G4 may each include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof.

The first to fourth gate electrodes G1, G2, G3, and G4 may each include a conductive metal oxide, a conductive metal oxynitride, or the like, and my include an oxidized form of the aforementioned materials.

The first gate electrode G1 may be disposed between a first source/drain pattern SDP1 and a third source/drain pattern SDP3, which will be described below. The second gate electrode G2 may be disposed between the first source/drain pattern SDP1 and the second source/drain pattern SDP2.

In some embodiments, the first gate electrode G1 may be the gate electrode of the first pass transistor PG1. The second gate electrode G2 may be the gate electrodes of the first pull-down transistor PD1 and the first pull-up transistor PU1.

The first gate spacer GS1 may be disposed on a side wall of the first gate electrode G1. The first gate spacer GS1 is not in contact with the first gate electrode G1. A first gate insulating film GI1 may be disposed between the first gate electrode G1 and the first gate spacer GS1.

The second gate spacer GS2 may be disposed on the side wall of the second gate electrode G2. The second gate spacer GS2 is not in contact with the second gate electrode G2. A second gate insulating film GI2 may be disposed between the second gate electrode G2 and the second gate spacer GS2.

Each of the first gate spacer GS1 and the second gate spacer GS2 may each include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof.

The first gate insulating film GI1 may extend the part between the first gate electrode G1 and the upper surface of the first lower pattern BP1, and the part between the first gate electrode G1 and the first sheet pattern SP1. Further, the first gate insulating film GI1 may be formed between the first gate electrode G1 and the first gate spacer GS1.

The second gate insulating film GI2 may be formed between the second gate electrode G2 and the upper surface of the first lower pattern BP1, between the second gate electrode G2 and the upper surface of the second lower pattern BP2, between the second gate electrode G2 and the first sheet pattern SP1, and between the second gate electrode G2 and the second sheet pattern SP2. Further, the second gate insulating film GI2 may be formed between the second gate electrode G2 and the second gate spacer GS2.

Each of the first and second gate insulating films GI1 and GI2 may include silicon oxide, silicon oxynitride, silicon nitride or a high dielectric constant material having a higher dielectric constant than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although each of the first and second gate insulating films GI1 and GI2 is shown to be a single film, this is only for convenience of explanation, and the embodiment is not limited thereto. Each of the first and second gate insulating films GI1 and GI2 may include a plurality of films.

A semiconductor device according to some embodiments may include an NC (Negative Capacitance) FET that uses a negative capacitor. For example, each of the first and second gate insulating films GI1 and GI2 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. The thickness of the ferroelectric material film may be, for example, but not limited to, 0.5 to 10 nm. Since a critical thickness that exhibits the ferroelectric properties may vary for each ferroelectric material, the thickness of the ferroelectric material film may vary depending on the ferroelectric material.

As an example, each of the first and second gate insulating films GI1 and GI2 may include one ferroelectric material film. As another example, each of the first and second gate insulating films GI1 and GI2 may include a plurality of ferroelectric material films spaced apart from each other. Each of the first and second gate insulating films GI1 and GI2 may have a stacked film structure in which the plurality of ferroelectric material films and the plurality of paraelectric material films are alternately stacked.

A first gate capping film GC1 may be disposed on the upper surface of the first gate electrode G1 and the upper surface of the first gate spacer GS1. A second gate capping film GC2 may be disposed on the upper surface of the second gate electrode G2 and the upper surface of the second gate spacer GS2. Each of the first gate capping film GC1 and the second gate capping film GC2 may include, for example, at least one of silicon nitride (SiN), silicon oxynitride (SiON), silicon oxide (SiO₂), silicon carbonitride (SiCN), silicon oxycarbonitride (SiOCN), and combinations thereof.

A first source/drain pattern SDP1 may be disposed on the first active pattern AP1. The first source/drain pattern SDP1 may be disposed on the first lower pattern BP1. The first source/drain pattern SDP1 may be disposed between the first gate electrode G1 and the second gate electrode G2.

A second source/drain pattern SDP2 may be disposed on the first active pattern AP1. The second source/drain pattern SDP2 may be disposed on the first lower pattern BP1. The second source/drain pattern SDP2 may be opposite to the first source/drain pattern SDP1 with the second gate electrode G2 therebetween. That is, the first source/drain pattern SDP1 may be disposed on one side of the second gate electrode G2, and the second source/drain pattern SDP2 may be disposed on the other side of the second gate electrode G2.

A third source/drain pattern SDP3 may be disposed on the first active pattern AP1. The third source/drain pattern SDP1 may be disposed on the first lower pattern BP1. The third source/drain pattern SDP3 may be opposite to the first source/drain pattern SDP1 with the first gate electrode G1 therebetween. That is, the first source/drain pattern SDP1 may be disposed on one side of the first gate electrode G1, and the third source/drain pattern SDP3 may be disposed on the other side of the first gate electrode G1.

A fourth source/drain pattern SDP4 may be disposed on the second active pattern AP2. The fourth source/drain pattern SDP4 may be disposed on the second lower pattern BP2. The fourth source/drain pattern SDP4 may be spaced apart from the first source/drain pattern SDP1 in the third direction D3. The fourth source/drain pattern SDP4 may be disposed on one side of the second gate electrode G2.

A fifth source/drain pattern SDP5 may be disposed on the second active pattern AP2. The fifth source/drain pattern SDP5 may be disposed on the second lower pattern BP2. The fifth source/drain pattern SDP5 may be spaced apart from the second source/drain pattern SDP2 in the third direction D3. The fifth source/drain pattern SDP5 may be disposed on the other side of the second gate electrode G2. That is, the fourth source/drain pattern SDP4 and the fifth source/drain pattern SDP5 may be opposite to each other with the second gate electrode G2 therebetween.

In some embodiments, the first source/drain pattern SDP1 may be a source pattern of the first pass transistor PG1, and at the same time the first source/drain pattern SDP1 may be a drain pattern of the first pull-down transistor PD1. The second source/drain pattern SDP2 may be a source pattern of the first pull-down transistor PD1. The third source/drain pattern SDP3 may be a drain pattern of the first pass transistor PG1. The fourth source/drain pattern SDP4 may be a drain pattern of the first pull-up transistor PU1. The fifth source/drain pattern SDP5 may be a source pattern of the first pull-up transistor PU1.

Each of the first to fifth source/drain patterns SDP1, SDP2, SDP3, SDP4, and SDP5 may include an epitaxial pattern. Each of the first to fifth source/drain patterns SDP1, SDP2, SDP3, SDP4, and SDP5 may include a semiconductor material. The first to fifth source/drain patterns SDP1, SDP2, SDP3, SDP4, and SDP5 may be included in a source/drain of a transistor that uses the first sheet pattern SP1 or the second sheet pattern SP2 as a channel region.

The first source/drain pattern SDP1, the second source/drain pattern SDP2, and the third source/drain pattern SDP3 may be connected to a channel region of the first active pattern AP1 that is used as a channel. For example, the first source/drain pattern SDP1, the second source/drain pattern SDP2, and the third source/drain pattern SDP3 may be connected to the first sheet pattern SP1.

The fourth source/drain pattern SDP4 and the fifth source/drain pattern SDP5 may be connected to a channel region of the second active pattern AP2 that is used as a channel. For example, the fourth source/drain pattern SDP4 and the fifth source/drain pattern SDP5 may be connected to the second sheet pattern SP2.

An etching stop film 160 may extend along the profiles of the upper surface of the field insulating film 105, the side walls of the first and second spacers GS1 and GS2, the first source/drain pattern SDP1, the second source/drain pattern SDP2, the third source/drain patterns SDP3, the fourth source/drain pattern SDP4 and the fifth source/drain pattern SDP5. In some embodiments, the etching stop film 160 is not disposed on the side walls of the first and second gate capping films GC1 and GC2. That is, each of the first and second gate capping films GC1 and GC2 may be disposed on the upper surface of the etching stop film 160. Also, the side walls of the etching stop film 160 may be connected to the outer walls of the first and second gate capping films GC1 and GC2. Unlike the shown example, the etching stop film 160 may be disposed on the side walls of the first and second gate capping films GC1 and GC2.

The etching stop film 160 may include a material having an etching selectivity with respect to a first interlayer insulating film 190, which will be described below. The etching stop film 160 may include a nitride-based insulating material. For example, it may include at least one of silicon nitride (SiN), silicon oxynitride (SiON), oxycarbonitride (SiOCN), silicon boronitride (SiBN), silicon oxyboronitride (SiOBN), and combinations thereof.

The first interlayer insulating film 190 is disposed on the etching stop film 160. The first interlayer insulating film 190 may be formed on the field insulating film 105. The first interlayer insulating film 190 may be disposed on the first source/drain pattern SDP1, the second source/drain pattern SDP2, the third source/drain pattern SDP3, the fourth source/drain pattern SDP4, and the fifth source/drain pattern SDP5. The first interlayer insulating film 190 may not cover the upper surfaces of the first and second gate capping films GC1 and GC2. For example, the upper surface of the first interlayer insulating film 190 may be coplanar with the upper surfaces of the first and second gate capping films GC1 and GC2.

The first interlayer insulating film 190 may include, for example, at least one of silicon oxide, silicon nitride, silicon oxynitride, and a low dielectric constant material. The low dielectric constant material may include, for example, but not limited to, at least one of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

A first gate contact CB1 may be disposed on the first gate electrode G1. The first gate contact CB1 may be electrically connected to the first gate electrode G1. The first gate contact CB1 may be electrically connected to a word line WL, which will be described below. That is, the word line WL may be electrically connected to the first gate electrode G1 through the first gate contact CB1. Further, a gate contact may also be disposed on the third gate electrode G3. Another word line and the third gate electrode G3 may be electrically connected through the gate contact.

A second gate contact CB2 is disposed on the second gate electrode G2. The second gate contact CB2 may be electrically connected to the second gate electrode G2. The second gate contact CB2 may be electrically connected to the first source/drain contact CA1 through the node pattern ND. That is, the same signal may be applied to the second gate electrode G2, the first source/drain pattern SDP1, and the fourth source/drain pattern SDP4 through the node pattern ND.

The first source/drain contact CA1 may be disposed on the first source/drain pattern SDP1 on the first active pattern AP1. The first source/drain contact CA1 may be disposed on the fourth source/drain pattern SDP4 on the second active pattern AP2. That is, the first source/drain pattern SDP1 and the fourth source/drain pattern SDP4 may be electrically connected to each other through the first source/drain contact CA1.

A third source/drain contact CA3 may be disposed on the third source/drain pattern SDP3 on the first active pattern AP1. A fifth source/drain contact CA5 may be disposed on the fifth source/drain pattern SDP5 on the second active pattern AP2.

The first source/drain contact CA1 passes through the etching stop film 160, and may be connected to the first source/drain pattern SDP1 and the fourth source/drain pattern SDP4. The first source/drain contact CA1 may be disposed inside the first interlayer insulating film 190. The first source/drain contact CA1 may be surrounded by the first interlayer insulating film 190.

The third source/drain contact CA3 passes through the etching stop film 160, and may be connected to the third source/drain pattern SDP3. The third source/drain contact CA3 may be disposed inside the first interlayer insulating film 190. The third source/drain contact CA3 may be surrounded by the first interlayer insulating film 190.

The fifth source/drain contact CA5 passes through the etching stop film 160, and may be connected to the fifth source/drain pattern SDP5. The fifth source/drain contact CA5 may be disposed inside the first interlayer insulating film 190. The fifth source/drain contact CA5 may be surrounded by the first interlayer insulating film 190.

A first contact silicide film 151 may be disposed between the first source/drain contact CA1 and the first source/drain pattern SDP1. Although the first contact silicide film 151 is shown as being formed along a profile of an interface between the first source/drain pattern SDP1 and the first source/drain contact CA1, the embodiment is not limited thereto.

Similarly, a fourth contact silicide film 154 may be disposed between the first source/drain contact CA1 and the fourth source/drain pattern SDP4. A third contact silicide film 153 may be disposed between the third source/drain contact CA3 and the third source/drain pattern SDP3. A fifth contact silicide film 155 may be disposed between the fifth source/drain contact CA5 and the fifth source/drain pattern SDP5.

Each of the first contact silicide film 151, the third contact silicide film 153, the fourth contact silicide film 154, and the fifth contact silicide film 155 may include, for example, a metal silicide material.

The first interlayer insulating film 190 does not cover the upper surfaces of the first source/drain contact CA1, the third source/drain contact CA3, and the fifth source/drain contact CA5. As an example, the upper surfaces of the first source/drain contact CA1, the third source/drain contact CA3, and the fifth source/drain contact CA5 do not protrude above the upper surfaces of the first and second gate capping films GC1 and GC2. The upper surfaces of the first source/drain contact CA1, the third source/drain contact CA3, and the fifth source/drain contact CA5 may be coplanar with the upper surfaces of the first and second gate capping films GC1 and GC2.

In some embodiments, the first source/drain contact CA1 may include a first source/drain barrier film CA1a, and a first source/drain filling film CA1b on the first source/drain barrier film CA1a. The third source/drain contact CA3 may include a third source/drain barrier film CA3a, and a third source/drain filling film CA3b on the third source/drain barrier film CA3a. The fifth source/drain contact CA5 may include a fifth source/drain barrier film CA5a, and a fifth source/drain filling film CA5b on the fifth source/drain barrier film CA5a.

Because the first source/drain barrier film CA1a, the third source/drain barrier film CA3a, and the fifth source/drain barrier film CA5a are substantially the same, and the first source/drain filling film CA1b, the third source/drain filling film CA3b and the fifth source/drain filling film CA5b are substantially the same, only the first source/drain barrier film CA1a and the first source/drain filling film CA1b will be described below.

The first source/drain barrier film CA1a may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and two-dimensional (2D) material. In the semiconductor device according to some embodiments, the two-dimensional material may be a metallic material and/or a semiconductor material. The 2D material may include a 2D allotrope or a 2D compound, and may include, but not limited to, at least one of graphene, molybdenum disulfide (MoS₂), molybdenum diselenide (MoSe₂), tungsten diselenide (WSe₂), and tungsten disulfide (WS₂). That is, since the above-mentioned 2D materials are only listed by way of example, the 2D materials that may be included in the semiconductor device of the present disclosure are not limited by the above-mentioned materials.

The first source/drain filling film CAlb may include, for example, at least one of aluminum (Al), tungsten (W), cobalt (Co), ruthenium (Ru), silver (Ag), gold (Au), manganese (Mn), and molybdenum (Mo).

Although first source/drain filling film CA1b is shown to include a plurality of conductive films, the embodiment is not limited thereto. Unlike the shown example, the first source/drain contact CA1 may be a single film.

In some embodiments, the second gate contact CB2 may include a second gate contact barrier film CB2a and a second gate contact filling film CB2b. The material included in the second gate contact barrier film CB2a may be the same as the material included in the first source/drain barrier film CA1a. The material included in the second gate contact filling film CB2b may be the same as the material included in the first source/drain filling film CA1b.

The semiconductor device according to some embodiments may include a first power supply wiring PL1, a second power supply wiring PL2, a first bit line BL1, a word line WL, and a second bit line BL2.

The first power supply wiring PL1 may be disposed on the second surface 100b of the substrate 100. The first power supply wiring PL1 may be disposed below the pass transistor, the pull-down transistor, and the pull-up transistor. The first power supply wiring PL1 may be electrically connected to the second source/drain pattern SDP2. The first power supply wiring PL1 may apply the negative voltage VSS to the second source/drain pattern SDP2.

Specifically, a first via VA1 may be disposed between the first power supply wiring PL1 and the second source/drain pattern SDP2. The first via VA1 may extend toward the substrate 100 on the upper surface of the first power supply wiring PL1. The upper surface of the first power supply wiring PL1 may face the second surface 100b of the substrate 100.

The first via VA1 may pass through the substrate 100 and the first lower pattern BP1, and be directly connected to the second source/drain pattern SDP2. A second contact silicide film 152 may be formed between the first via VA1 and the second source/drain pattern SDP2.

The first via VA1 may include a first via barrier film VA1a, and a first via filling film VA1b on the first via barrier film VA1a. The material included in the first via barrier film VA1a may be the same as the material included in the first source/drain barrier film CA1a. The material included in the first via filling film VA1b may be the same as the material included in the first source/drain filling film CA1b.

The first power supply wiring PL1 may extend in the third direction D3. The first power supply wiring PL1 may extend in the same direction as the extension direction of the gate electrodes G1, G2, G3, and G4. The first power supply wiring PL1 may be electrically connected to the source patterns of the pull-down transistors included in a plurality of cells. Since the first power supply wiring PL1 is disposed on the second surface 100b of the substrate 100, the degree of freedom in design of other wirings may increase. Accordingly, a semiconductor device having improved reliability may be fabricated.

The first power supply wiring PL1 may include a first power supply wiring barrier film PL1a, and a first power supply wiring filling film PL1b on the first power supply wiring barrier film PL1a. The material included in the first power supply wiring barrier film PL1a may be the same as the material included in the first source/drain barrier film CA1a. The material included in the first power supply wiring filling film PL1b may be the same as the material included in the first source/drain filling film CA1b.

The first power supply wiring PL1 may be surrounded by the lower insulating film 102. The lower insulating film 102 may be disposed on the second surface 100b of the substrate 100. The lower insulating film 102 may include, for example, at least one of silicon oxide, silicon nitride, silicon oxynitride, and a low dielectric constant material. The low dielectric constant material may include, for example, but not limited to, at least one of, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

The second power supply wiring PL2 may be disposed on the first surface 100a of the substrate 100. The second power supply wiring PL2 may be disposed between the second active pattern AP2 and the third active pattern AP3 from viewpoint of a plan view. The second power supply wiring PL2 may be disposed above the pass transistor, the pull-down transistor, and the pull-up transistor. The second power supply wiring PL2 may be electrically connected to the fifth source/drain pattern SDP5. The second power supply wiring PL2 may apply the positive voltage VDD to the fifth source/drain pattern SDP5.

Specifically, a third via VA3 may be disposed between the second power supply wiring PL2 and the fifth source/drain pattern SDP5. The third via VA3 may extend toward the substrate 100 from the lower surface of the second power supply wiring PL2. The lower surface of the second power supply wiring PL2 may face the first surface 100a of the substrate 100. The third via VA3 may pass through an upper stop film 191 and the second interlayer insulating film 192, and be directly connected to the fifth source/drain contact CA5.

The third via VA3 may include a third via barrier film VA3a, and a third via filling film VA3b on the third via barrier film VA3a. The material included in the third via barrier film VA3a may be the same as the material included in the first source/drain barrier film CA1a. The material included in the third via filling film VA3b may be the same as the material included in the first source/drain filling film CA1b.

The second power supply wiring PL2 may extend in the second direction D2. The second power supply wiring PL2 may extend in a direction different from the first power supply wiring PL1. The second power supply wiring PL2 may extend in the same direction as the extension direction of the active pattern. The second power supply wiring PL2 may be electrically connected to source patterns of the pull-up transistors included in a plurality of cells.

The second power supply wiring PL2 may include a second power supply wiring barrier film PL2a, and a second power supply wiring filling film PL2b on the second power supply wiring barrier film PL2a. The material included in the second power supply wiring barrier film PL2a may be the same as the material included in the first source/drain barrier film CA1a. The material included in the second power supply wiring filling film PL2b may be the same as the material included in the first source/drain filling film CA1b.

The upper stop film 191 is disposed on the first interlayer insulating film 190. A second interlayer insulating film 192 is disposed on the upper stop film 191. The upper stop film 191 may include a material having an etching selectivity with respect to the second interlayer insulating film 192. The upper stop film 191 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), aluminum oxide (AlO), aluminum nitride (AlN), aluminum oxycarbide (AlOC), and combinations thereof. Although the upper stop film 191 is shown as being a single film, the embodiment is not limited thereto. Unlike the shown example, the upper stop film 191 may not be formed. The second interlayer insulating film 192 may include, for example, at least one of silicon oxide, silicon nitride, silicon carbonitride, silicon oxynitride, and a low dielectric constant material.

The first bit line BL1 may be disposed on the first surface 100a of the substrate 100. The first bit line BL1 may be disposed above the pass transistor, the pull-down transistor, and the pull-up transistor. The first bit line BL1 may be electrically connected to the third source/drain pattern SDP3. The first bit line BL1 may apply a signal to the third source/drain pattern SDP3.

Specifically, the second via VA2 may be disposed between the first bit line BL1 and the third source/drain pattern SDP3. The second via VA2 may extend toward the substrate 100 on the lower surface of the first bit line BL1. The lower surface of the first bit line BL1 may face the first surface 100a of the substrate 100. The second via VA2 may pass through the upper stop film 191 and the second interlayer insulating film 192, and may be directly connected to the third source/drain contact CA3.

The second via VA2 may include a second via barrier film VA2a, and a second via filling film VA2b on the second via barrier film VA2a. The material included in the second via barrier film VA2a may be the same as the material included in the first source/drain barrier film CA1a. The material included in the second via filling film VA2b may be the same as the material included in the first source/drain filling film CA1b.

The first bit line BL1 may extend in the second direction D2. The first bit line BL1 may extend in a direction different from that of the first power supply wiring PL1. The first bit line BL1 may extend in the same direction as that of the second power supply wiring PL2. The first bit line BL1 and the second power supply wiring PL2 may be disposed at the same vertical level. The first bit line BL1 and the second power supply wiring PL2 may be spaced apart from each other in the third direction D3. The first bit line BL1 may extend in the same direction as the extension direction of the active pattern.

The first bit line BL1 may include a first bit line barrier film BL1a, and a first bit line filling film BL1b on the first bit line barrier film BL1a. The material included in the first bit line barrier film BL1a may be the same as the material included in the first source/drain barrier film CA1a. The material included in the first bit line filling film BL1b may be the same as the material included in the first source/drain filling film CA1b.

In some embodiments, the first bit line BL1 is disposed on the first active pattern AP1. The second bit line BL2 is disposed on the fourth active pattern AP4. The first bit line BL1 may be electrically connected to the drain patterns of the first pass transistors included in the plurality of cells. The second bit line BL2 may be electrically connected to the drain patterns of the second pass transistors included in the plurality of cells.

The first bit line BL1 and the second power supply wiring PL2 may be surrounded by a third interlayer insulating film 193. The third interlayer insulating film 193 may include, for example, at least one of silicon oxide, silicon nitride, silicon carbonitride, silicon oxynitride, and a low dielectric constant material.

The word line WL may extend in the third direction D3. The word line WL may extend in a direction different from the first bit line BL1 and the second bit line BL2. The word line WL may be disposed at a higher vertical level than the first bit line BL1 and the second bit line BL2 on the basis of the first surface 100a of the substrate 100. The word line WL may be connected to the first gate electrode G1 through the first gate contact CB1. The word line WL may apply a signal to the gate electrode of the first pass transistor. Although not shown, the word line WL may also be connected to the third gate electrode G3. The word line WL may apply the signal to the gate electrode of the second pass transistor through another gate contact.

The word line WL may include a word line barrier film WLa, and a word line filling film WLb on the word line barrier film WLa. A material included in the word line barrier film WLa may be the same as a material included in the first source/drain barrier film CA1a. A material included in the word line filling film WLb may be the same as a material included in the first source/drain filling film CA1b.

The word line WL may be surrounded by a fourth interlayer insulating film 194. The fourth interlayer insulating film 194 may include, for example, at least one of silicon oxide, silicon nitride, silicon carbonitride, silicon oxynitride, and a low dielectric constant material.

The semiconductor device according to some embodiments may further include a node pattern ND. The node pattern ND may be disposed on the first source/drain contact CA1 and the second gate contact CB2. A signal may be applied to the first source/drain pattern SDP1, the fourth source/drain pattern SDP4, and the fourth gate electrode G4 through the node pattern ND, the first source/drain contact CA1, and the second gate contact CB2. The node pattern ND may pass through the second interlayer insulating film 192 and the upper stop film 191, and be connected to the first source/drain contact CA1 and the second gate contact CB2.

The node pattern ND may include a node pattern barrier film NDa, and a node pattern filling film NDb on the node pattern barrier film NDa. The material included in the node pattern barrier film NDa may be the same as the material included in the first source/drain barrier film CA1a. The material included in the node pattern filling film NDb may be the same as the material included in the first source/drain filling film CA1b.

Although the transistors included in the semiconductor device according to some embodiments are shown to be an MBCFET, technical ideas of the present disclosure are not limited thereto. It goes without saying that the transistors may be a FinFET or a GAAFET including nanowires.

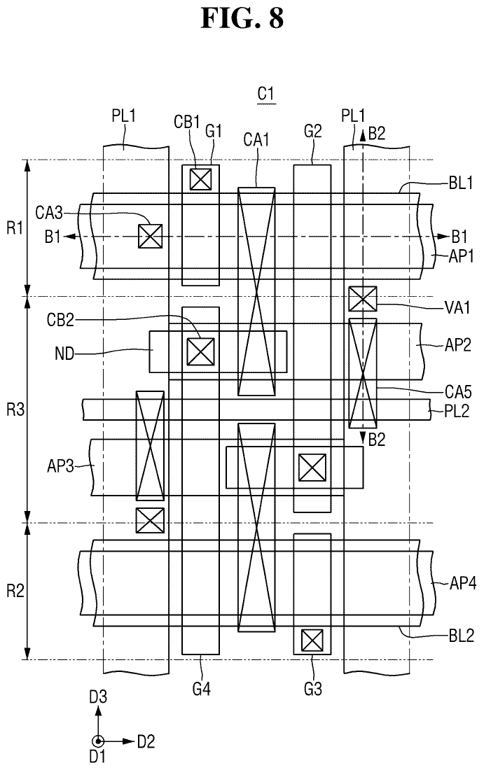

Hereinafter, a semiconductor device according to some other embodiments of the present disclosure will be described with reference to FIGS. 8 to 11. For convenience of explanation, repeated contents of those described using FIGS. 3 to 7 will be briefly explained or omitted.

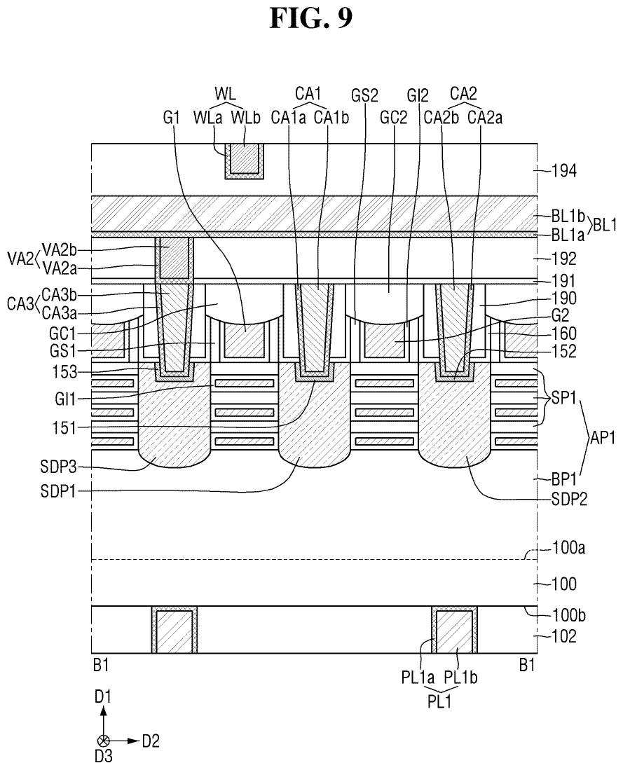

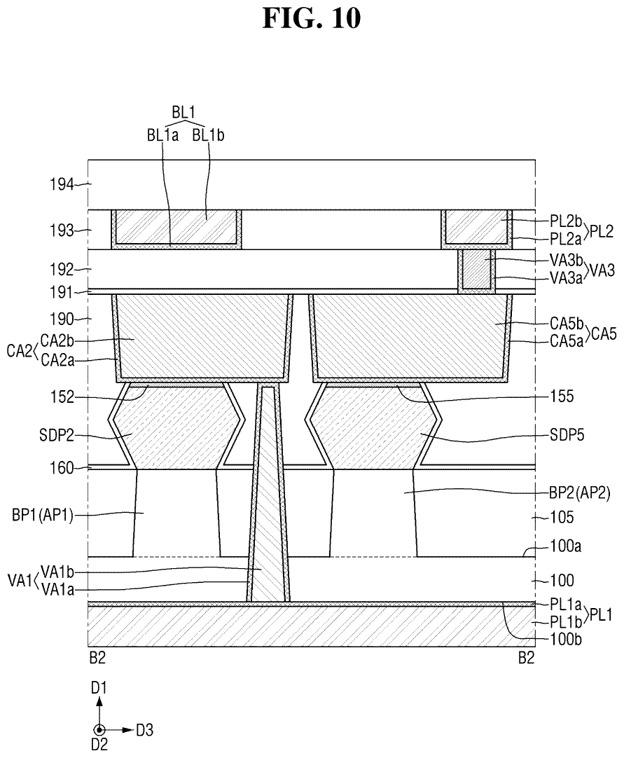

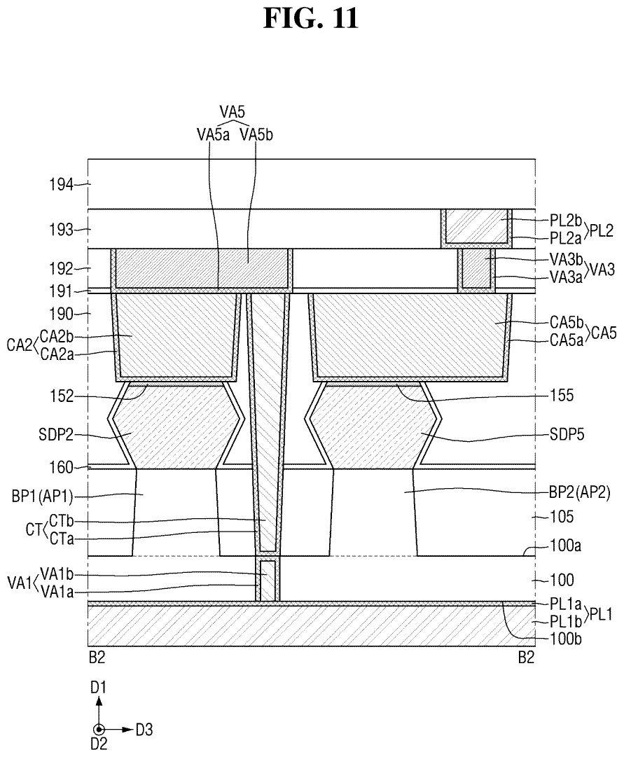

FIG. 8 is an example layout diagram for explaining a semiconductor device according to some other embodiments of the present disclosure. FIG. 9 is an example cross-sectional view taken along a line B1-B1 of FIG. 8. FIGS. 10 and 11 are example cross-sectional views taken along a line B2-B2 of FIG. 8.

First, referring to FIGS. 8 to 10, in the semiconductor device according to some embodiments, the first via VA1 may not be directly connected to the second source/drain pattern SDP2. The semiconductor device according to some embodiments may include a second source/drain contact CA2.

The second source/drain contact CA2 may be disposed on the second source/drain pattern SDP2 on the first active pattern AP1. The second source/drain contact CA2 may pass through the etching stop film 160 and the first interlayer insulating film 190, and be connected to the second source/drain pattern SDP2. A second contact silicide film 152 may be disposed between the second source/drain contact CA2 and the second source/drain pattern SDP2.

The second source/drain contact CA2 may include a second source/drain barrier film CA2a, and a second source/drain filling film CA2b on the second source/drain barrier film CA2a. The material included in the second source/drain barrier film CA2a may be the same as the material included in the first source/drain barrier film CA1a. The material included in the second source/drain filling film CA2b may be the same as the material included in the first source/drain filling film CA1b.

The first via VA1 is not directly connected to the second source/drain pattern SDP2. The first via VA1 may be directly connected to the second source/drain contact CA2. That is, the first power supply wiring PL1 and the second source/drain pattern SDP2 may be electrically connected through the first via VA1 and the second source/drain contact CA2.

The first via VA1 may pass through the substrate 100, the field insulating film 105, and the etching stop film 160, and be connected to the lower surface of the second source/drain contact CA2. The lower surface of the second source/drain contact CA2 may face the first surface 100a of the substrate 100.

Referring to FIG. 11, the semiconductor device according to some embodiments may further include a wiring contact CT and a fifth via VA5.

The fifth via VA5 may be disposed on the second source/drain contact CA2. The fifth via VA5 may be electrically connected to the second source/drain contact CA2, and may be electrically connected to the wiring contact CT. The wiring contact CT may pass through the first interlayer insulating film 190, the etching stop film 160, and the field insulating film 105 from the lower surface of the fifth via VA5, and may be connected to the first via VA1.

That is, the first power supply wiring PL1 may be electrically connected to the second source/drain pattern SDP2 through the first via VA1, the wiring contact CT, the fifth via VA5, and the second source/drain contact CA2.

The fifth via VA5 may include a fifth via barrier film VA5a, and a fifth via filling film VA5b on the fifth via barrier film VA5a. The material included in the fifth via barrier film VA5a may be the same as the material included in the first source/drain barrier film CA1a. The material included in the fifth via filling film VA5b may be the same as the material included in the first source/drain filling film CA1b.

The wiring contact CT may include a wiring contact barrier film CTa, and a wiring contact filling film CTb on the wiring contact barrier film CTa. The material included in the wiring contact barrier film CTa may be the same as the material included in the first source/drain barrier film CA1a. The material included in the wiring contact filling film CTb may be the same as the material included in the first source/drain filling film CA1b.

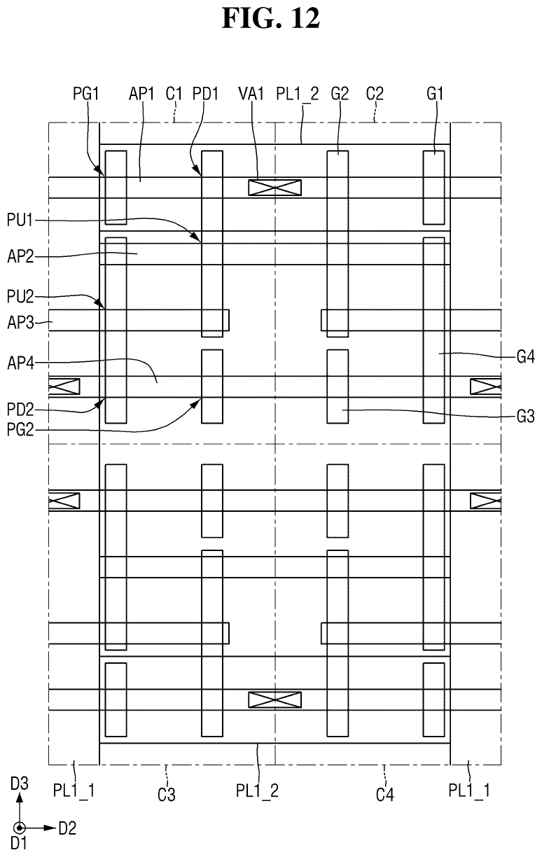

Hereinafter, a semiconductor device according to some other embodiments of the present disclosure will be described with reference to FIGS. 12 to 17. For convenience of explanation, repeated contents of those described using FIGS. 3 to 7 will be briefly explained or omitted.

FIGS. 12 to 16 are example diagrams for explaining a semiconductor device according to some other embodiments of the present disclosure.

Referring to FIG. 12, the first power supply wiring PL1 may include a first portion PL1_1 and a second portion PL1_2.

The first portion PL1_1 of the first power supply wiring PL1 may extend in the third direction D3, and the second portion PL1_2 of the first power supply wiring PL1 may extend in the second direction D2. The second portion PL1_2 of the first power supply wiring PL1 may extend in the second direction D2 between the first portions PL1_1 of the pair of first power supply wirings PL1. The second portion PL1_2 of the first power supply wiring PL1 may be connected to each of the first portions PL1_1 of the pair of first power supply wirings PL1.

That is, the first power supply wiring PL1 may be formed as a rectangular closed curve from viewpoint of a plan view.

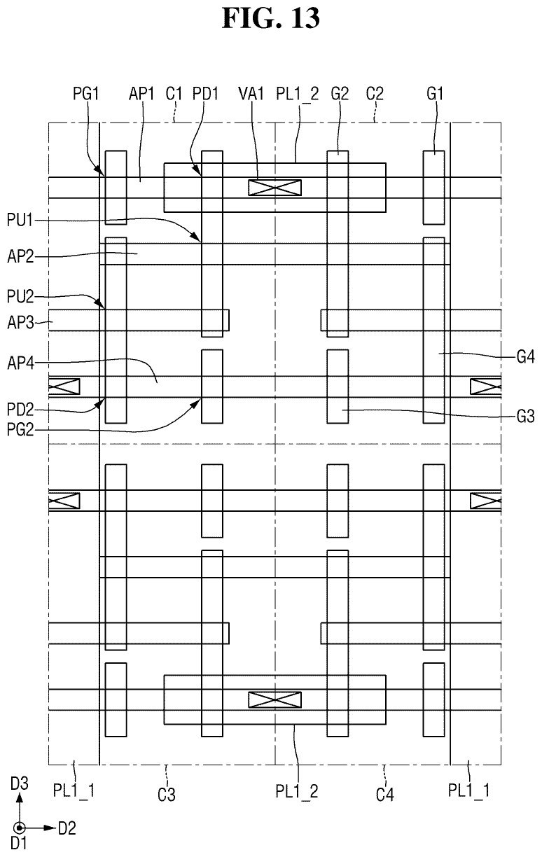

Referring to FIG. 13, the first power supply wiring PL1 may include a first portion PL1_1 and a second portion PL1_2.

Although the first portion PL1_1 of the first power supply wiring PL1 extends in the third direction D3, and the second portion PL1_2 of the first power supply wiring PL1 may be disposed in an island shape. That is, the second portion PL1_2 of the first power supply wiring PL1 may be spaced apart from the first portion PL1_1 of the first power supply wiring PL1.

A part of the second portion PL1_2 of the first power supply wiring PL1 may be disposed in an island shape at a position that overlaps the source pattern of the first pull-down transistor PD1 of the first cell region C1, and the source pattern of the first pull-down transistor PD1 of the second cell region C2 in the first direction D1.

The other part of the second portion PL1_2 of the first power supply wiring PL1 may be disposed in an island shape at a position that overlaps the source pattern of the second pull-down transistor PD2 of the third cell region C3, and the source pattern of the second pull-down transistor PD2 of the fourth cell region C4 in the first direction D1.

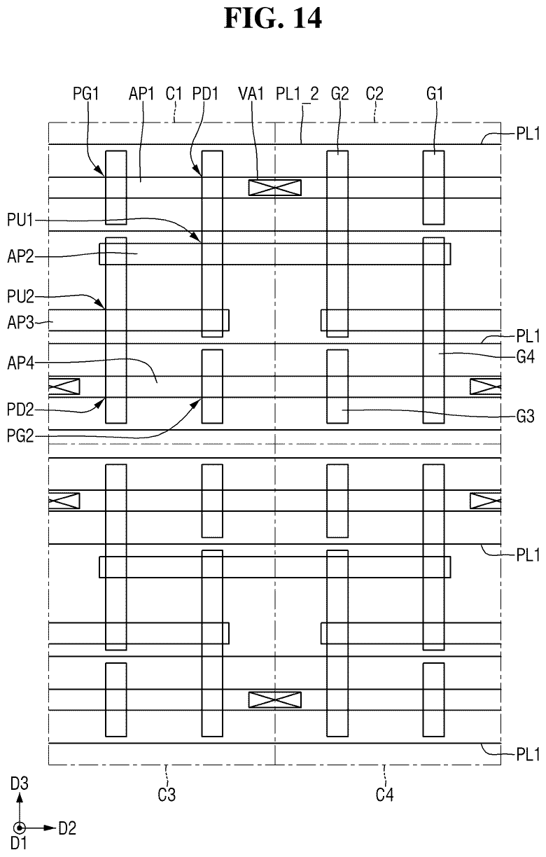

Referring to FIG. 14, the first power supply wiring PL1 may extend in the second direction D2. The first power supply wiring PL1 may extend in the same direction as the extension direction of the active pattern of the pass transistor. The first power supply wirings PL1 may be spaced apart from each other in the third direction D3.

A part of the first power supply wiring PL1 overlaps the source pattern of the first pull-down transistor PD1 of the first cell region C1, and the source pattern of the first pull-down transistor PD1 of the second cell region C2 in the first direction D1.

The other part of the first power supply wiring PL1 overlaps the source pattern of the second pull-down transistor PD2 of the first cell region C1, and the source pattern of the second pull-down transistor PD2 of the second cell region C2 in the first direction D1.

The other part of the first power supply wiring PL1 overlaps the source pattern of the first pull-down transistor PD1 of the third cell region C3, and the source pattern of the first pull-down transistor PD1 of the fourth cell region C4 in the first direction D1.

The other part of the first power supply wiring PL1 overlaps the source pattern of the second pull-down transistor PD2 of the third cell region C3, and the source pattern of the second pull-down transistor PD2 of the fourth cell region C4 in the first direction D1.

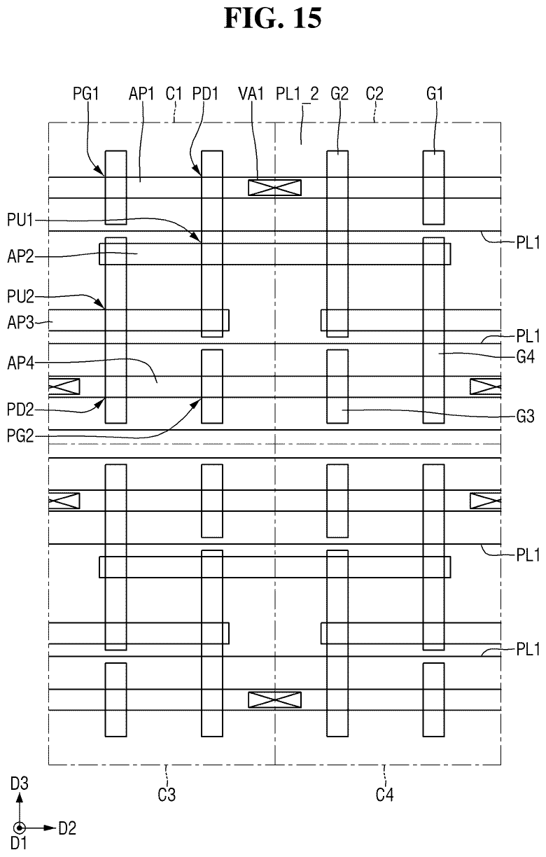

Referring to FIG. 15, the first power supply wiring PL1 may extend in the second direction D2. The first power supply wiring PL1 may extend in the same direction as the extension direction of the active pattern of the pass transistor. The first power supply wirings PL1 may be spaced apart from each other in the third direction D3.

The first power supply wiring PL1 may overlap all four adjacent cells C1, C2, C3, and C4 in the first direction D1.

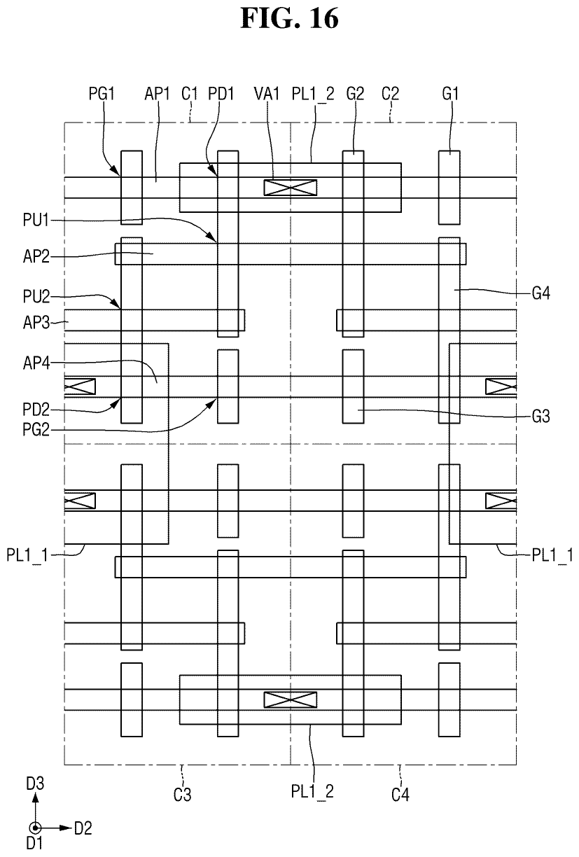

Referring to FIG. 16, all the first power supply wirings PL1 may be disposed in an island shape. The first power supply wiring PL1 may include a first portion PL1_1 and a second portion PL1_2.

The first portion PL1_1 of the first power supply wiring PL1 may extend in the third direction D3, and the second portion PL1_2 of the first power supply wiring PL1 may extend in the second direction D2. The first portion PL1_1 of the first power supply wiring PL1 is connected to the source pattern of the second pull-down transistor and the source pattern of the first pull-down transistor of a pair of cells adjacent to each other in the third direction D3. The second portion PL1_2 of the first power supply wiring PL1 is connected to the source pattern of the first pull-down transistor and the source pattern of the second pull-down transistor of a pair of cells adjacent to each other in the second direction D2.

Although embodiments of the present disclosure have been described with reference to the accompanying drawings, inventive concepts in the present disclosure are not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor device comprising:
a substrate including a first surface and a second surface opposing each other in a first direction;
a first active pattern on the first surface and extending in a second direction, the second direction intersecting the first direction;
a second active pattern on the first surface and spaced apart from the first active pattern in a third direction, the third direction intersecting the first direction and the second direction, and the second active pattern extending in the second direction;
a first gate electrode intersecting the first active pattern and extending in the third direction;
a second gate electrode spaced apart from the first gate electrode in the second direction, the second gate electrode intersecting the first active pattern and the second active pattern;
a first source/drain pattern on the first active pattern, the first source/drain pattern disposed between the first gate electrode and the second gate electrode;
a second source/drain pattern on the first active pattern, the second gate electrode being between the first source/drain pattern and the second source/drain;
a third source/drain pattern on the second active pattern and spaced apart from the first source/drain pattern in the third direction; and
a first power supply wiring on the second surface and electrically connected to the second source/drain pattern, wherein
the first source/drain pattern and the third source/drain pattern are electrically shared through a same node, and
a first portion of the first power supply wiring extends in the third direction from below the second source/drain pattern.

2. The semiconductor device of claim 1, wherein
a second portion of the first power supply wiring extends in the second direction from below the second source/drain pattern, and
the first portion of the first power supply wiring and the second portion of the first power supply wiring are electrically connected to each other.

3. The semiconductor device of claim 1, further comprising:
a first via extending from an upper surface of the first power supply wiring toward the substrate.

4. The semiconductor device of claim 3, wherein
the first via passes through the substrate and the first active pattern, and
the first via is directly connected to the second source/drain pattern.

5. The semiconductor device of claim 3, further comprising:
a second source/drain contact on the second source/drain pattern,
wherein the first via is connected to the second source/drain contact.

6. The semiconductor device of claim 1,
wherein the first gate electrode is not on the second active pattern.

7. The semiconductor device of claim 1, further comprising:
a fourth source/drain pattern apart from the first source/drain pattern with the first gate electrode therebetween;
a bit line connected to the fourth source/drain pattern; and
a word line connected to the first gate electrode.

8. The semiconductor device of claim 7, further comprising:
a fifth source/drain pattern on the second active pattern and apart from the third source/drain pattern with the second gate electrode therebetween; and
a second power supply wiring on the first surface, wherein
the second power supply wiring is electrically connected to the fifth source/drain pattern.

9. The semiconductor device of claim 8, wherein
the first power supply wiring is configured to apply a negative voltage to the second source/drain pattern, and
the second power supply wiring is configured to apply a positive voltage to the fifth source/drain pattern.

10. The semiconductor device of claim 8, wherein
the first power supply wiring is configured to apply a positive voltage to the second source/drain pattern, and
the second power supply wiring is configured to apply a negative voltage to the fifth source/drain pattern.

11. The semiconductor device of claim 1, wherein
the first active pattern includes a first lower pattern and a plurality of first sheet patterns,
the first lower pattern extends in the second direction,
the plurality of first sheet patterns are spaced apart from the first lower pattern in the first direction, and
the plurality of first sheet patterns are connected to the first source/drain pattern, the second source/drain pattern, and the third source/drain pattern.

12. A semiconductor device comprising:
a substrate including a first surface and a second surface opposite to each other in a first direction;
a pass transistor on the first surface of the substrate;
a pull-down transistor sharing an active region with the pass transistor;
a pull-up transistor sharing a gate electrode with the pull-down transistor;
a word line electrically connected to a gate electrode of the pass transistor;
a bit line electrically connected to a drain pattern of the pass transistor;
a first power supply wiring electrically connected to a source pattern of the pull-down transistor; and
a second power supply wiring electrically connected to a source pattern of the pull-up transistor, wherein
a source pattern of the pass transistor, a drain pattern of the pull-down transistor, and a drain pattern of the pull-up transistor are electrically connected through one node,
the first power supply wiring is on the second surface,
the word line, the bit line, and the second power supply wiring are on the first surface, and
a first portion of the first power supply wiring extends in a direction parallel to an extension direction of a gate electrode of the pass transistor.

13. The semiconductor device of claim 12, wherein
a second portion of the first power supply wiring extends in a direction parallel to an extension direction of an active pattern of the pass transistor, and
the first portion of the first power supply wiring and the second portion of the first power supply wiring are electrically connected.

14. The semiconductor device of claim 12,
in a plan view, a shape of the first power supply wiring includes a rectangular closed curve.

15. The semiconductor device of claim 12,
wherein the bit line and the second power supply wiring extend in a same direction.

16. The semiconductor device of claim 12, wherein
the first power supply wiring is configured to apply a negative voltage a source pattern of the pull-down transistor, and
the second power supply wiring is configured to apply a positive voltage to a source pattern of the pull-up transistor.

17. A semiconductor device comprising:
a substrate including a first NMOS region, a second NMOS region, a PMOS region between the first NMOS region and the second NMOS region, the substrate including a first surface and a second surface opposite to each other in a first direction;
a first pass transistor and a first pull-down transistor on the first surface of the substrate of the first NMOS region;
a second pass transistor and a second pull-down transistor on the first surface of the substrate of the second NMOS region;
a first pull-up transistor on the first surface of the substrate of the PMOS region, the first pull-up transistor sharing a gate electrode with the first pull-down transistor;
a second pull-up transistor on the first surface of the substrate of the PMOS region and sharing a gate electrode with the second pull-down transistor;
a first power supply wiring configured to apply a negative voltage to each of a source pattern of the first pull-down transistor and a source pattern of the second pull-down transistor; and
a second power supply wiring configured to apply a positive voltage to each of a source pattern of the first pull-up transistor and a source pattern of the second pull-up transistors, wherein
the first pass transistor and the first pull-down transistor share an active region,
the second pass transistor and the second pull-down transistor share a same active region,
a source pattern of the first pass transistor, a drain pattern of the first pull-down transistor, and a drain pattern of the first pull-up transistor are electrically connected through one first node,
a source pattern of the second pass transistor, a drain pattern of the second pull-down transistor, and a drain pattern of the second pull-up transistor may be electrically connected through one second node,
the first power supply wiring is on the second surface of the substrate,
the second power supply wiring is on the first surface of the substrate,
the first power supply wiring extends in a direction parallel to an extension direction of the gate electrode of the first pass transistor and an extension direction of the gate electrode of the second pass transistor, and
the second power supply wiring extends in a direction parallel to an extension direction of an active pattern of the first pass transistor and an extension direction of an active pattern of the second pass transistor.

18. The semiconductor device of claim 17, wherein
the first pass transistor, the second pass transistor, the first pull-down transistor, the second pull-down transistor, the first pull-up transistor, and the second pull-up transistor each are a MBCFET.

19. The semiconductor device of claim 17, wherein
a first portion of the first power supply wiring is connected to a source pattern of the first pull-down transistor,
a second portion of the first power supply wiring is connected to a source pattern of the second pull-down transistor, and
the first portion of the first power supply wiring and the second portion of the first power supply wiring are spaced apart from each other.

20. The semiconductor device of claim 17, further comprising:
a word line connected to a gate electrode of each of the first pass transistor and the second pass transistor, wherein
the word line is on the first surface of the substrate, and
a level of the word line is a higher vertical level than a level the second power supply wiring with respect to the first surface of the substrate.
